(19) United States
(12) Patent Application Publication
(10) Pub. No.: US 2005/0263863 A1
(43) Pub. Date: Dec. 1, 2005

(54) Semiconductor device and a method of manufacturing the same

(76) Inventors: Toshio Sasaki, Mizuho (JP); Fujio Ito, Hanno (JP); Hiromichi Suzuki, Katsushika (JP)

Correspondence Address: Antonelli, Terry, Stout & Kraus, LLP;Suite 1800, 1300 North Seventeenth Street, Arlington, VA, 22209, US

(21) Appl. No.: 11/140,394

(22) Filed: May 31, 2005

(30) Foreign Application Priority Data
Jun. 1, 2004 (JP) 2004-162854

(51) Int. Cl. H01L 23/48; H01L 21/44

(52) U.S. Cl. 257/676; 438/123; 257/692

(57) ABSTRACT

Miniaturization in a semiconductor device which has a chip part is attained. A QFP having the chip part includes a semiconductor chip, a plurality of inner leads arranged around the semiconductor chip, a sheet member which connects with the end part of the inner lead via insulating adhesive and which connects with the semiconductor chip via adhesive, a plurality of outer leads which are respectively integral with an inner lead, a plurality of wires which connect the pads of the semiconductor chip and a plurality of inner leads, respectively, and a bar lead arranged along the periphery of a plurality of inner leads in the domain between the semiconductor chip and the plurality of inner leads. In the domain between the semiconductor chip and a plurality of inner leads, the chip part which constitutes a surface mounting part is mounted on the bar lead, while being arranged beneath the wire.

### CROSS-REFERENCE TO RELATED APPLICATION

The present application claims priority from Japanese patent application No. 2004-162854, filed on Jun. 1, 2004, the content of which is hereby incorporated by reference into this application.

### BACKGROUND OF THE INVENTION

This invention relates in general to a semiconductor device and to a method of manufacture thereof, and, more particularly, the invention relates to technology that is applicable to a semiconductor device which has a chip part and to a method of manufacture thereof.

In a conventional electronic device (semiconductor device), an integrated circuit constituent element and a non-integrated circuit constituent element, which constitute a first electric circuit and which are mutually connected, are formed as a standard package, and then covering fabrication is carried out by provision of a covering fabrication layer (for example, refer to Patent Reference 1).

A conventional electric power unit is provided with an energy supply circuit which supplies energy at a predetermined timing, and the provision of a conservation-of-energy circuit which receives the energy supplied from the energy supply circuit is important so that energy is saved (for example, refer to Patent Reference 2).

A conventional semiconductor device can supply power for every circuit part by use of a bus bar for connecting the power supply to every circuit part in a semiconductor chip. By efficiently employing the use of a bus bar which is connectable regardless of the pitch of inner leads, making the pitch of pads smaller than the pitch of the inner leads, and providing an alternating pad arrangement, the number of pads for the supply of power can be increased, or a lead which has been conventionally used for the supply of power can be used for signals (for example, refer to Patent Reference 3).

[Patent Reference 1] Japanese Unexamined Patent Publication No. Hei 10(1998)-209365 (FIG. 1)

[Patent Reference 2] Japanese Unexamined Patent Publication No. 2002-305248 (FIG. 1)

[Patent Reference 3] WO 03/105226 A1 Official Report (FIG. 56)

### SUMMARY OF THE INVENTION

Generally, since a parasitic element (R/C/L) as used in a semiconductor device tends to become large, a big mounting area, about which a part for the loss is considered, is needed in the circuit in which a semiconductor chip is combined with an external element. That is, in order to prevent the performance from falling due to a parasitic element, a big area is needed for mounting such elements.

This inventor has considered the miniaturization of a semiconductor device which has a chip part. As a result, a problem has been formed in that it is difficult to incorporate a chip part in a general-purpose type semiconductor device, and the package size becomes special as well.

This inventor has found a further problem in that, when an external element is an inductance element especially, if the inductance element is formed on a semiconductor chip, the area occupied by the inductance element will become large and the semiconductor chip will be enlarged, with the result that a cost overrun is caused because the yield of the semiconductor chip drops, or the number of picking of the semiconductor chip decreases.

Although Patent Reference 1 (Japanese Unexamined Patent Publication No. Hei 10(1998)-209365) describes a structure in which chip parts are consolidated with a semiconductor chip, there is no statement therein about technology which aims at effective use of the space in a semiconductor package.

Although Patent Reference 2 (Japanese Unexamined Patent Publication No. 2002-305248) describes technology in which a DC-DC converter is provided in which an inductance element was formed on a semiconductor chip, in an effort to obtain an improvement in the conversion efficiency, there is no statement therein about technology which prevents enlargement of the semiconductor chip.

Although Patent Reference 3 (WO 03/105226 A1 Official Report) describes a structure in which a ring-like bus bar is arranged between chip inner leads and a semiconductor element, there is no statement therein about a structure in which a chip part is embedded in the package.

An object of the present invention is to provide a semiconductor device and a method of manufacture thereof which can attain miniaturization in a semiconductor device which has a chip part.

Another object of the present invention is to provide a semiconductor device and method of manufacture thereof which can attain an improvement in an electrical property in a semiconductor device which has a chip part.

Yet another object of the present invention is to provide a semiconductor device and method of manufacture thereof which can achieve simplification of a mounting process.

The above and other objects and new features of this invention will become clear from the following description and the accompanying drawings.

An outline of a typical aspects and features of the present invention will be briefly explained.

In one aspect of the present invention, there is a semiconductor device, which comprises: a plurality of first leads; a sheet member connected to end part of each of the plurality of first leads; a semiconductor chip, having a semiconductor element and a plurality of electrodes on a main surface thereof, being arranged inside the plurality of leads, and being further connected with the sheet member; a plurality of second leads arranged around the semiconductor chip; a plurality of conductive wires which electrically connect the electrodes of the semiconductor chip and the plurality of second leads, respectively; and a chip part formed as a surface mounting part, which is arranged beneath a wire and is disposed in the area between the semiconductor chip and the plurality of first leads.

In another aspect of the present invention, there is a semiconductor device comprising: a plurality of first leads; a sheet member connected to an end part of each of the plurality of first leads; a semiconductor chip, having a semiconductor element and a plurality of electrodes on a main surface thereof, being arranged inside the plurality of first leads, and being further connected with the sheet member; a plurality of second leads arranged around the semiconductor chip; a plurality of conductive wires which electrically connect the electrodes of the semiconductor chip, and the plurality of second leads, respectively; a sealed body sealing the semiconductor chip and the plurality of wires; and a first passive part, provided with an inductance element, that is arranged outside of the semiconductor chip and inside of the sealed body.

In a further aspect of the present invention, there is a method of manufacture of a semiconductor device, which comprises the steps of: preparing a lead frame to which a sheet member and the end parts of a plurality of leads are connected via insulating adhesive; mounting a chip part as a surface mounting part in an area outside of a chip mounting part and inside of the plurality of leads on the sheet member; after mounting the chip part, mounting a semiconductor chip in the chip mounting part of the sheet member; electrically connecting each of the plurality of leads with a plurality of electrodes of a main surface of the semiconductor chip using a plurality of conductive wires, respectively; performing resin molding of the semiconductor chip and the plurality of leads, and forming a sealed body; and individually separating the plurality of leads from the lead frame.

The effect obtained by typical aspects and features of the invention will be explained briefly.

In a semiconductor device which has a chip part, the empty space beneath a connecting wire can be effectively used by arranging the chip part in the area between a semiconductor chip and a plurality of leads and under a connecting wire. Thereby, miniaturization of a semiconductor device which has a chip part can be attained. By arranging a chip part inside the sealed body of a semiconductor device, as compared with the case where a chip part is mounted outside of a semiconductor device, the loss produced by a parasitic element (R/C/L) can be reduced, and the circuit can be made highly efficient.

### BRIEF DESCRIPTION OF THE DRAWINGS

FIG. 1 is a plan view of the inner structure of a sealed body, showing an example of the structure of a semiconductor device and the expansion connection diagram of chip parts representing an Embodiment 1 of the present invention;

FIG. 2 is a schematic diagram of the chip part in the Z section shown in FIG. 1;

FIG. 3 is a schematic diagram of a modification of the chip part of the Z section shown in FIG. 1;

FIG. 4 is a plan view of the inner structure of a sealed body, showing the structure of a semiconductor device representing a modification of the Embodiment 1 of the present invention;

FIG. 5 is a plan view of the inner structure of a sealed body, showing the structure of a semiconductor device and an expansion connection diagram of a chip part representing a modification of the Embodiment 1 of the present invention;

FIG. 6 is a diagram showing the connection state of the chip part shown in FIG. 5;

FIG. 7 is a plan view of the internal structure of a sealed body, showing the structure of a semiconductor device and an expansion connection diagram of a chip part representing a modification of Embodiment 1 of the present invention;

FIG. 8 is a plan view of the inner structure of a sealed body, showing the structure of a semiconductor device and an expansion connection diagram of a chip part representing a modification of Embodiment 1 of the present invention;

FIG. 9 is a schematic diagram showing the structure of a semiconductor device representing a modification of Embodiment 1 of the present invention;

FIG. 10 is a diagram showing the connection state of the chip parts shown in FIG. 9;

FIG. 11 is a circuit diagram and a characteristic diagram of the chip part shown in FIG. 10;

FIG. 12 is a circuit diagram of another chip part shown in FIG. 10;

FIG. 13 is a plan view of the semiconductor device representing a modification of Embodiment 1 of the present invention showing the connection state of chip parts;

FIG. 14 is a circuit block diagram showing the circuit composition of the semiconductor device shown in FIG. 13;

FIG. 15 is a circuit diagram showing an example of a voltage down circuit in the circuit composition shown in FIG. 14;

FIG. 16 is an equivalent circuit diagram using an example of the voltage down circuit shown in FIG. 15;

FIG. 17 is a circuit diagram of the circuit composition shown in FIG. 16;

FIG. 18 is an equivalent circuit diagram showing a modification of the voltage down circuit shown in FIG. 15;

FIG. 19 is a circuit diagram of the circuit composition shown in FIG. 18;

FIG. 20 is a circuit diagram showing an example of the boost circuit in the circuit composition shown in FIG. 14;

FIG. 21 is an equivalent circuit diagram showing an example of the boost circuit shown in FIG. 20;

FIG. 22 is a circuit diagram of the circuit composition shown in FIG. 21;

FIG. 23 is a plan view showing an example of the structure of a lead frame, and a chip part attachment state in the assembly of the semiconductor device shown in FIG. 1;

FIG. 24 is a plan view showing an example of the structure at the time of die-bonding completion in the assembly of the semiconductor device shown in FIG. 1;

FIG. 25 is a plan view showing an example of the structure at the time of wire bonding completion and resin molding completion in the assembly of the semiconductor device shown in FIG. 1;

FIG. 26 is a sectional view showing an example of the structure of a lead frame, and a chip part attachment state in the assembly of the semiconductor device shown in FIG. 1;

FIG. 27 is a sectional view showing an example of the structure at the time of die-bonding completion in the assembly of the semiconductor device shown in FIG. 1;

FIG. 28 is a sectional view showing an example of the structure at the time of wire bonding completion and resin molding completion in the assembly of the semiconductor device shown in FIG. 1;

FIG. 29 is a sectional view showing an example of the structure of a semiconductor device representing an Embodiment 2 of this invention;

FIG. 30 is a sectional view showing an example of the structure in which chip parts are not mounted in the semiconductor device as shown in FIG. 29; and

FIG. 31 is a sectional view showing the structure of a semiconductor device representing a modification of Embodiment 2 of the present invention.

### DETAILED DESCRIPTION OF THE PREFERRED EMBODIMENTS

In the following description of the embodiments, except for the case where it is especially required, an explanation of the same element or same portion is not repeated in principle.

In the following detailed description, when there is a necessity for the sake of convenience, the subject matter of the present invention will be divided into a plurality of sections or embodiments. However, except for the case where it is clearly evident, they are not mutually unrelated and one has a relation, such that it is a modification, represents details, or is a supplementary explanation, etc. of some or all of the others.

In the following description of the embodiments, when a number of elements (a number, a numerical value, a quantity, a range, etc. are included), etc., is mentioned, except for the case where it is shown especially clearly and where it is theoretically limited to a specific number, the numerical value may be considered as more than the specific number or less than the specific number instead of being limited to the specific number.

Hereafter, various embodiments of the present invention will be explained in detail based on the accompanying drawings. In the all of the drawings, the same reference number is used to identify a component which has the same function, and a repeated explanation thereof is omitted.

### Embodiment 1

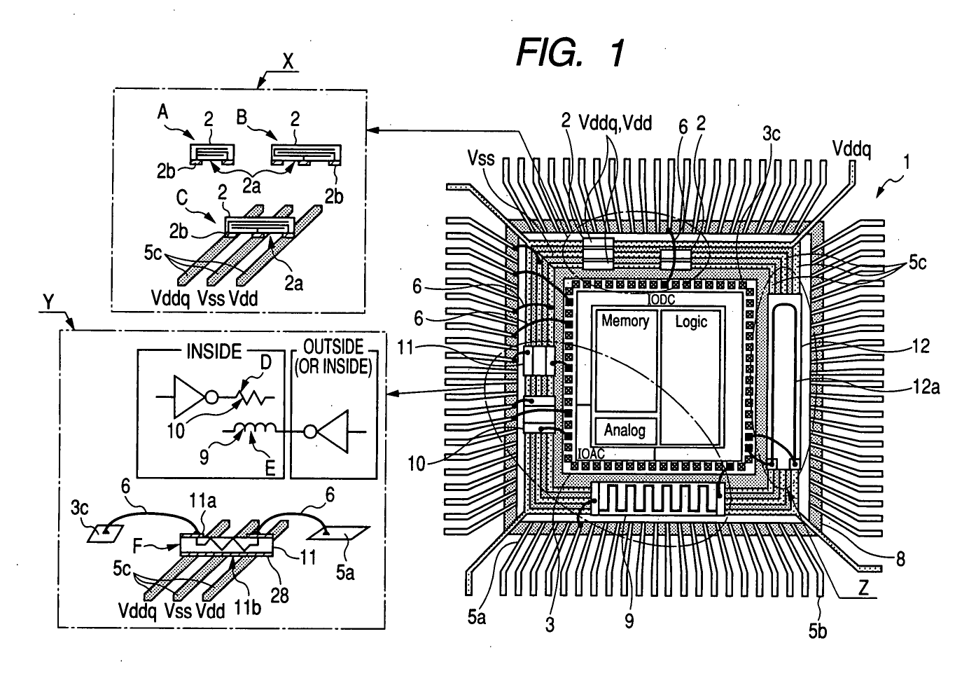

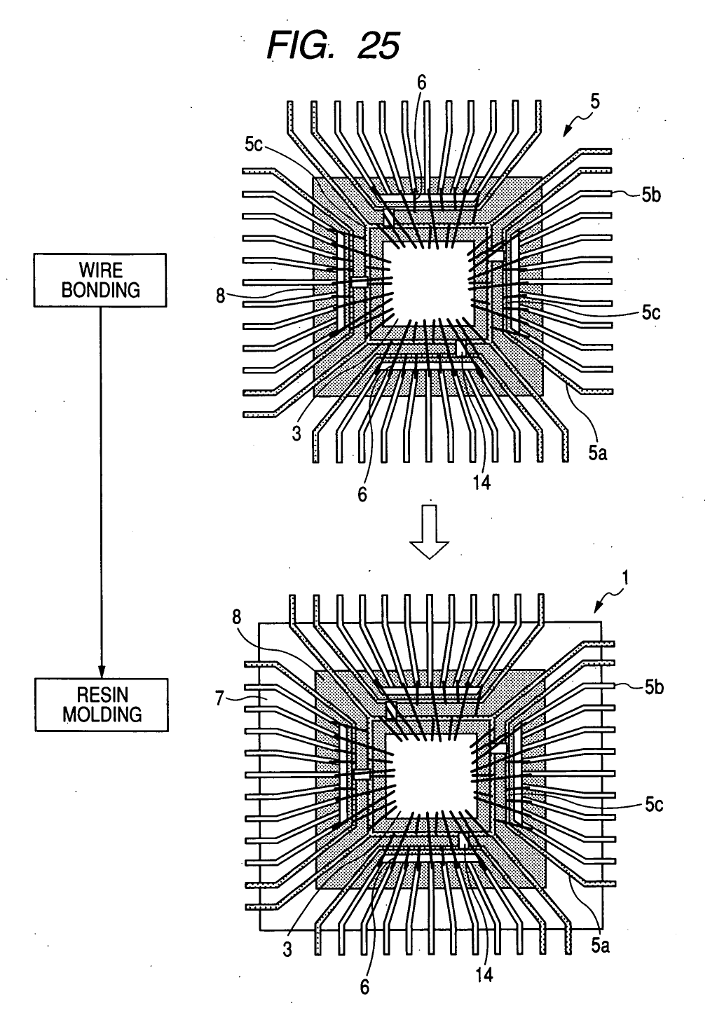

The semiconductor device of this Embodiment 1, as shown in FIG. 1, is in the form of a semiconductor package of the resin molding type, which has many pins, and in which chip parts have been arranged outside of the semiconductor chip 3 and inside of the sealed body 7 (refer to FIG. 25). Here, as an example, a QFP(Quad-Flat-Package) 1, is considered, in which there are a plurality of outer leads 5b projecting from each of four sides of the sealed body 7, with each outer lead 5b being formed by bending it in the shape of a gull wing.

In the case of a QFP 1 with many pins, the area per one lead Which can be provided becomes small as the end part by the side of the chip of each inner lead 5a approaches the semiconductor chip 3, and the lead density becomes high. Therefore, the distance at which the end part of each inner lead 5a can be brought close to the semiconductor chip 3 is limited. As a result, there is a tendency to provide an empty domain or space between the end part of each inner lead 5a and the semiconductor chip 3 in this basis, the QFP 1 of this Embodiment 1 effectively utilizes the empty domain between the end part of each inner lead 5a and the semiconductor chip 3 in the QFP 1 that has many pins. That is, by arranging chip parts in the empty domain or space between the semiconductor chip 3 and the end part of inner leads 5a, the QFP 1 can be miniaturized, and it becomes highly efficient.

This Embodiment 1 is directed to a case where a bar lead 5c, which is a common lead, is formed in the empty domain between the semiconductor chip 3 and the end part of the inner leads 5a.

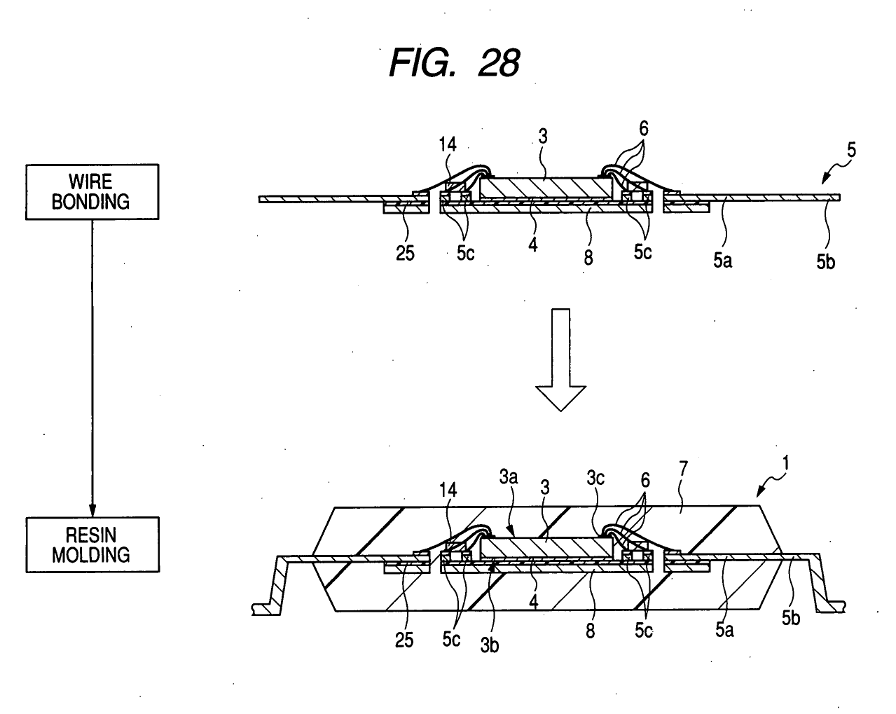

The detailed composition of the QFP 1 will be explained. The QFP 1 is a semiconductor device which has a semiconductor chip 3, and pads 3c, which are a plurality of electrodes disposed on the main surface 3a thereof, as shown in FIG. 28. In the semiconductor chip 3, integrated circuits, such as a Memory, a Logic circuit, an Analog circuit, a IOAC, and a IODC, are formed. There are inner leads 5a which constitute a plurality of leads arranged around the semiconductor chip 3, an insulating sheet member 8 which connects with the end part of the inner leads 5a via an insulating adhesive 25 and connects via adhesives, such as silver paste 4, to the back 3b of the semiconductor chip 3. A plurality of outer leads 5b, which respectively extend from an inner lead 5a, are exposed to the outside. A plurality of conductive wires 6 electrically connect the pads 3c of the semiconductor chip 3 to respective ones of the plurality of inner leads 5a, and bar leads (common leads) 5c being the shape of a plurality of rings are arranged along the periphery of the plurality of inner leads 5a in the area between the semiconductor chip 3 and a plurality of inner leads 5a. In the area between the semiconductor chip 3 and the plurality of inner leads 5a, various chip parts, which are surface mounting parts are mounted on the bar leads 5c, while being arranged beneath the wires 6.

For example, in the QFP 1 shown in FIG. 1, three bar leads 5c are arranged between a semiconductor chip 3 and the inner leads 5a. The chip parts shown in the X section of FIG. 1 are chip capacitors 2, and the general size (B) of the larger one is 0.6 mm×0.3 mm. The general size (A) of the smaller one is 0.4 mm×0.2 mm. Then, when the lead width of a bar lead 5c is set to 0.25 mm and the space between leads is set to 0.15 mm, the spacing becomes (0.25 mm+0.15 mm)×3=1.2 mm, and even the long-side direction (0.6 mm) of the chip capacitor 2 of the larger one can be fully accommodated on the three bar leads 5c.

As shown in the X section of FIG. 1, the three bar leads 5c are designed to carry Vddq, Vss, and Vdd, and the A and B chip capacitors 2 of the X section connect with Vss and Vdd, for example. The C chip capacitor 2 of the X section is connected with Vddq, Vss, and Vdd. It is preferred in that case to electrically connect the electrode 2b of each main surface 2a of the chip capacitor 2 and each bar lead 5c by direct solder connection. Thus, stabilization of a power supply/GND can be attained by arranging chip parts with the bypass capacitance element which connects between Vdd-Vss at the end part near the circuit of operation, and by connecting the chip part with the bar leads 5c by direct solder connection in that case.

Next, as shown in the Y section of FIG. 1, the D chip resistor 10 and the E chip inductor 9 are arranged on the outside of the semiconductor chip 3, and this arrangement is good also in the case of a boost circuit (DC converter), such as a regulator.

The chip resistor 11, with a dumping resistance element, is arranged on the bar leads 5c like the F chip part of the Y section of FIG. 1. One electrode 11a of this chip resistor 11 is connected to the pad 3c of the semiconductor chip 3 with a wire 6, and the other electrode 11a is connected to the inner lead 5a with another wire 6, thereby to reduce the bounce in the signal waveform. That is, the waveform disturbance of a signal can be eased, or radiation noise can be reduced.

The chip resistor 11 is connected to the bar leads 5c via an insulating adhesive 28. Namely, since the electrode 11a of the chip resistor 11 and the bar leads 5c of the lower part must be insulated from each other in this case, the back 11b of the chip resistor 11 is connected to the far leads 5c via the insulating adhesives 28. Thus, a chip part, such as the chip resistor 11, can be arranged on the bar leads 5c, and the space between the chip inner leads and the semiconductor chips can be utilized effectively.

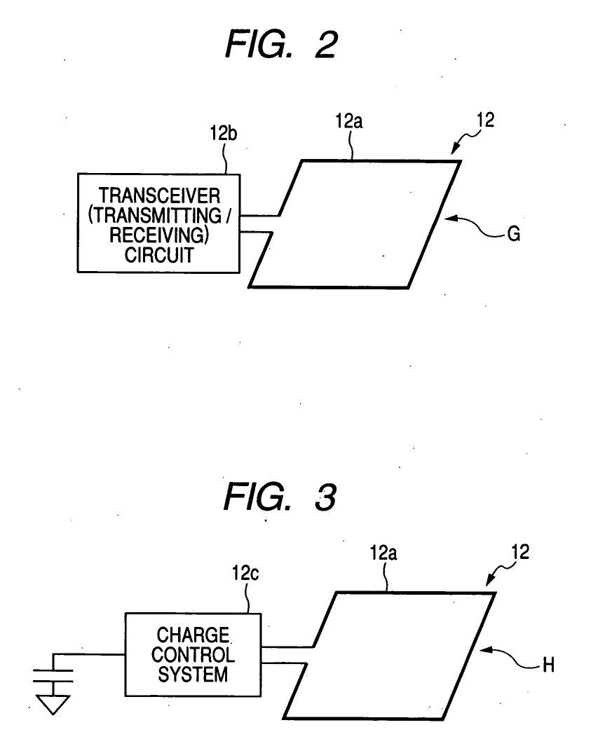

Next, the chip part of the Z section of FIG. 1 is the G antenna chip 12 having an antenna element 12a, as shown in FIG. 2. By connecting the antenna element 12a with the transmitting/receiving circuit 12b, it can be utilized as a transmitting/receiving antenna. The chip part of the Z section of FIG. 1 is utilizable also as an electromotive force generating means by electric wave reception by providing it as the H antenna chip 12 in which the antenna element 12a is connected to the charge control system 12c, as shown in FIG. 3.

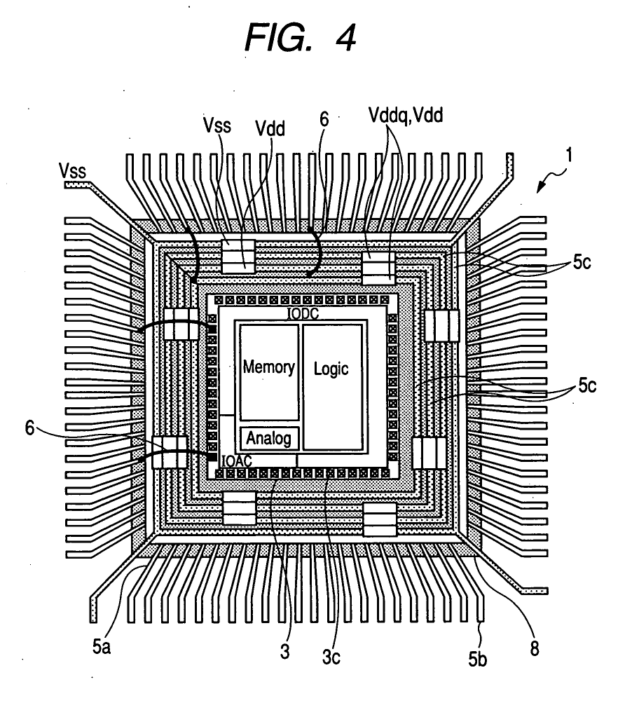

Next, in the modification shown in FIG. 4, four bar leads 5c are arranged between chip inner leads 5a, and the grounding potential of Vddq, Vss, and Vdd is arranged by turns. In this case, the chip part has no wire connection, but has a directly preferred connection using solder etc.

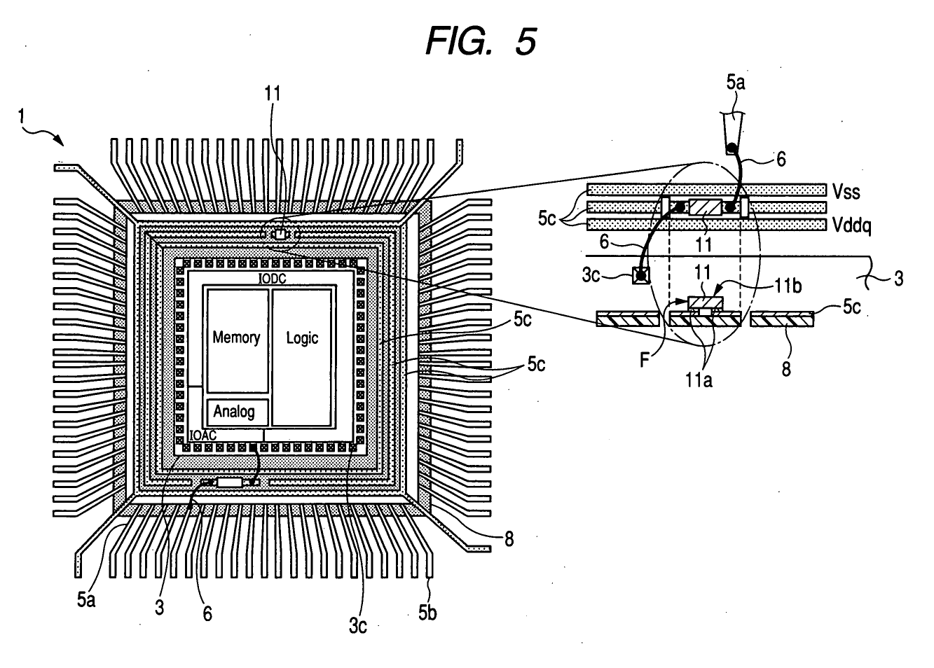

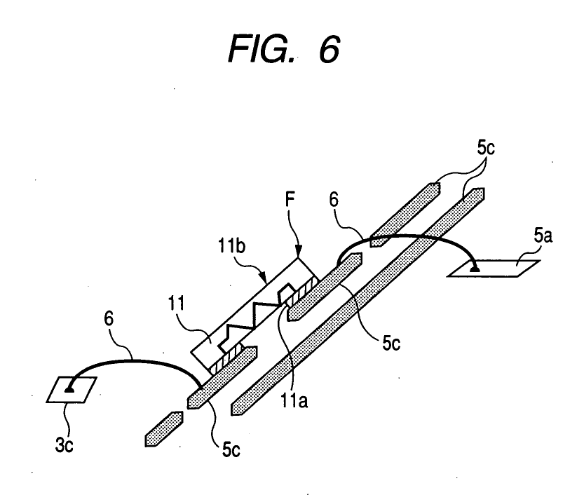

Like the F chip part of the Y section of FIG. 1, the modification of FIG. 5 shows a structure in which the wire height is low, when arranging the chip resistor 11, which serves as a dumping resistance element disposed on the bar leads 5c. That is, as shown in FIG. 6, the electrodes 1a of the chip resistor 11 are separately connected to two bar leads 5c, which were divided and were insulated mutually, using soldering (silver paste attachment is sufficient), etc. directly. Without a wire connection to the electrode 11a of the chip resistor 11, the pad 3c of the semiconductor chip 3 and the inner lead 5a are separately connected to two bar leads 5c which are individually connected to the electrodes 11a and are insulated from each other mutually.

Therefore, the electrodes 11a do not necessarily need to be formed on both the back and front sides of the chip resistor 11, but can just be formed on the chip resistor 11, in this case, at one side thereof.

Thereby, while being able to reduce the bounce in a signal wave form, since the chip resistor 11 serving as a dumping resistance element is positioned to intervene in the middle of the wire connection between the semiconductor chip 3 and the inner lead 5a, the wire height can be made low, since the wire connection is made to each bar lead 5c, as compared with the wire height of the F chip resistor 11 of the Y section of FIG. 1. As a result, in mounting the chip parts on bar leads, the structure which prevented a low height is avoided.

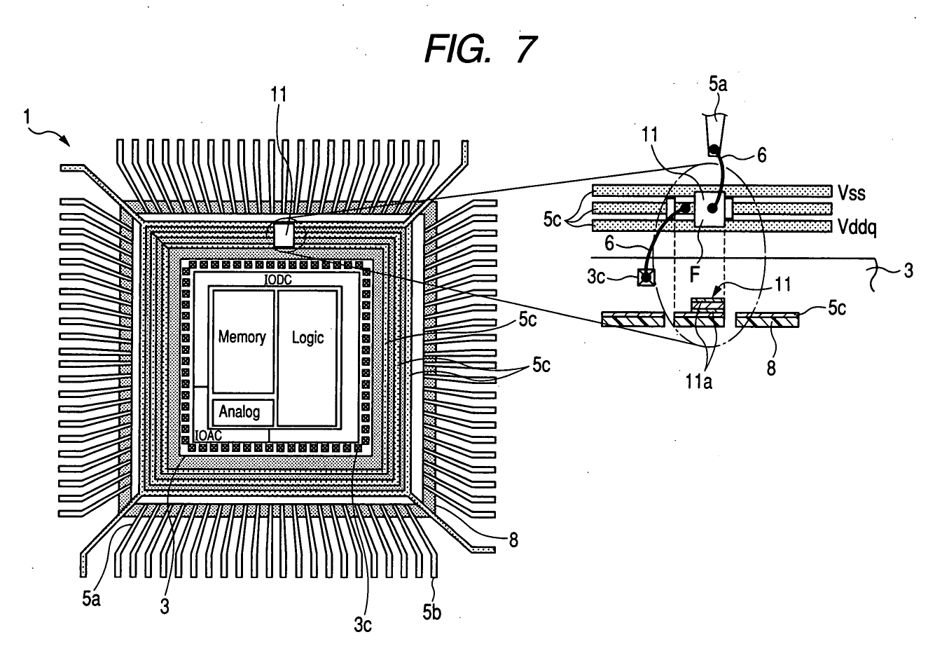

The modification shown in FIG. 7 involves a case where the electrodes 11a are formed on both the back and front sides of the chip resistor 11. In that case, the electrode 11a on the side of the surface is connected with the inner lead 5a using a wire 6, a solder connection of the electrode 11a on the back side is made with the bar lead 5c, and this bar lead 5c is further connected with the pad 3c of the semiconductor chip 3 via a wire 6. Thus, even in a case where the electrodes 11a are formed on both the back and front sides of the chip resistor 11, these electrodes 11a and the inner lead 5a and the pad 3c are connectable with wires 6.

A modification is shown in FIG. 8 in which a chip part is mounted on the sheet member 8 in an empty domain between a semiconductor chip 3 and the inner leads 5a where the bar lead 5c is not arranged, as shown in an enlarged plan view and an expanded sectional view. That is, a plurality of bar leads 5c are arranged along the periphery of inner leads 5a in the area between the semiconductor chip 3 and the plurality of inner leads 5a, and a chip part is arranged on the sheet member 8 in an area between the bar lead 5c arranged as the innermost among the bar leads 5c and the semiconductor chip 3. When the number of the bar leads 5c arranged between the chip and the inner leads 5a is comparatively small, such as 1-2, the area between the innermost bar lead 5c and the semiconductor chip 3 can be utilized effectively. The bounce of a signal waveform between the chip and the inner leads can be reduced by arranging the chip resistor 11 serving as a dumping resistance element as a chip part in that case.

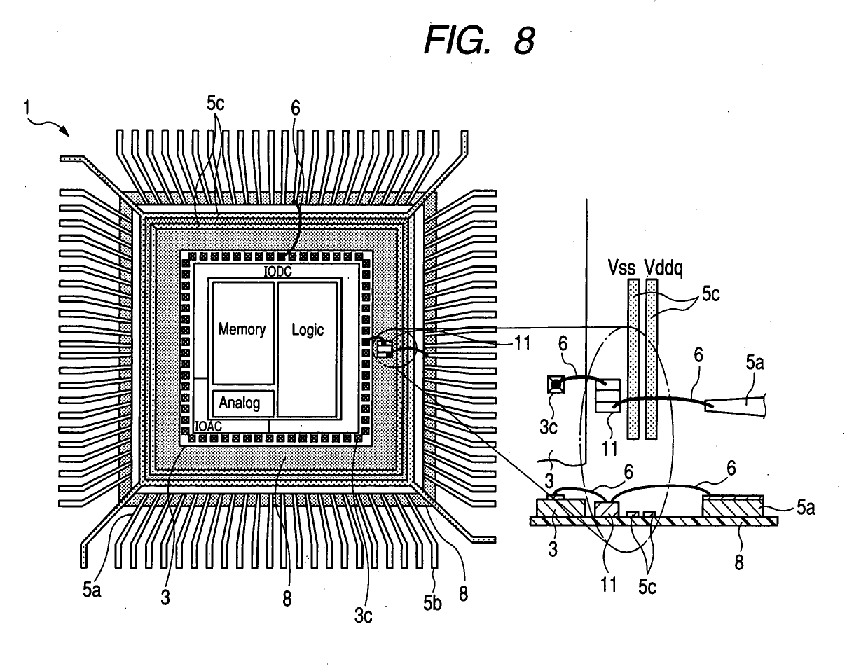

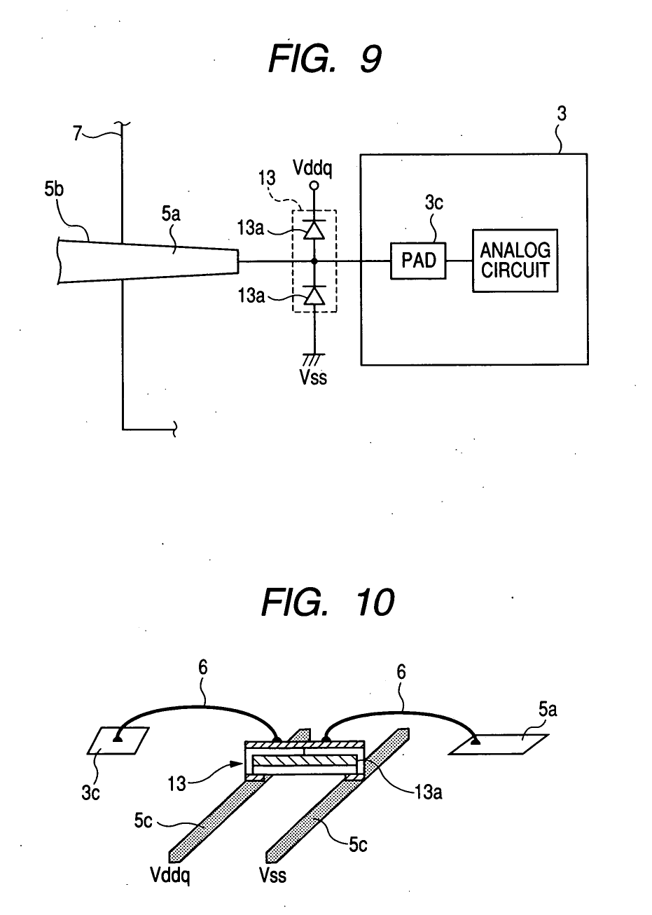

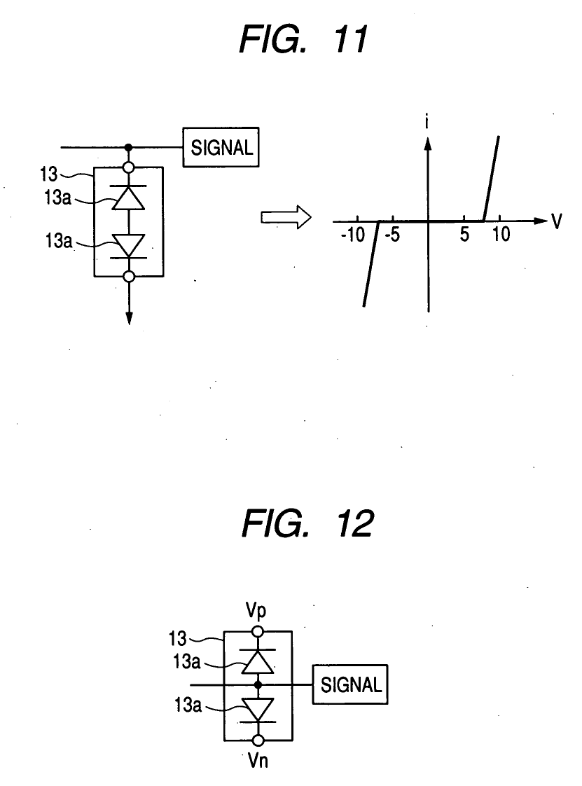

A modification is shown in FIG. 9 in which a chip part has a protection element. That is, between a semiconductor chip 3 and the inner leads 5a, a chip diode 13, which is a chip part with protection elements, such as the diodes 13a, is made to connect with each of the bar leads 5c electrically using soldering, etc., and the elements are arranged as shown in FIG. 10. When the protection element is an ESD(Electro Static Discharge) protection element, as shown in the example of FIG. 11 or FIG. 12, it can provide protection so that the noise produced by the voltage out of the range may not influence the signal between the chip and an inner lead. For example, when a voltage higher the than power supply potential is inputted from the inner lead 5a, the noise potential can be cut out by the chip diode 13 by positive or negative values. The chip diode 13 properly provides protection from the + side surge or protection from the − side surge, etc. The ESD protection element may be a resistance element.

A protection element also may be an EMC(Electro Magnetic Compatibility) protection element which consists of a ferrite chip and is similarly used as a measure against a power supply/signal noise, for example.

Next, a semiconductor device representing a modification, in which a chip part in which an inductance element has been built, will be explained.

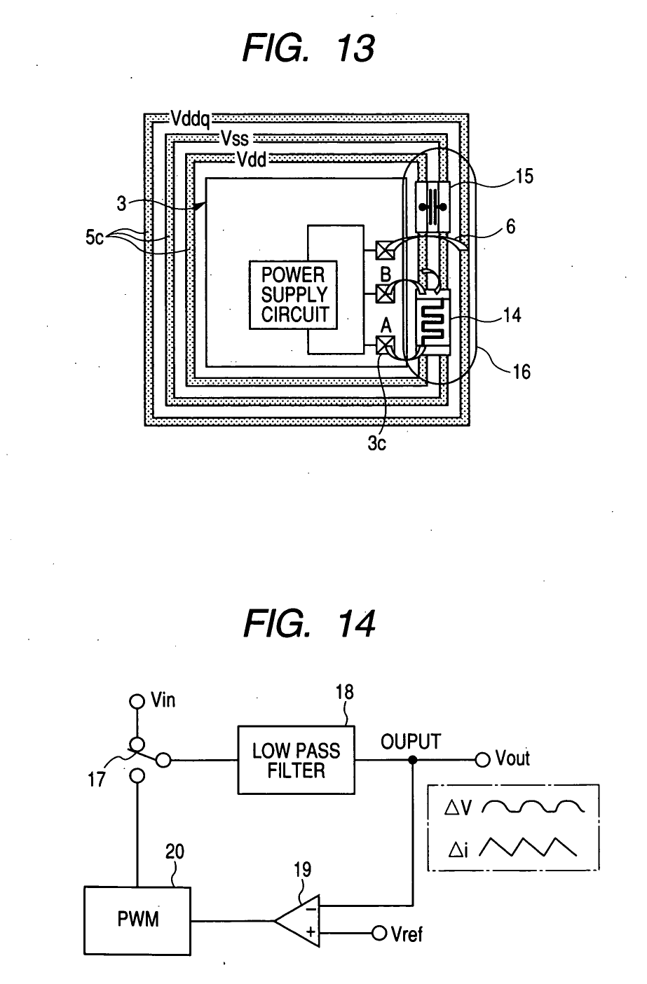

If it is desirable to form an inductance element on a chip in a semiconductor device, the chip area will become large and the yield will drop. Therefore, an inductance element is not formed on a chip, but the chip inductor 14 is arranged outside of the semiconductor chip 3 and inside the sealed body 7 (refer to FIG. 25), like the semiconductor device of the Embodiment 1 shown in FIG. 13. The chip capacitor 15 is also arranged in the same position, and the LC filter 16 is formed as a combination of the chip inductor 14 and the chip capacitor 15.

FIG. 14 is a circuit diagram of a power regulator, which comprises a switch SW17, a low pass filter 18, an error amplifier 19, a PWM(pulse width conversion control switching regulator)20, etc. However, if the chip inductor 14 and the chip capacitor 15 are formed on the chip when using the chip inductor 14 and the chip capacitor 15 for the low pass filter 18, the semiconductor chip 3 will become very large. Therefore, like the semiconductor device shown in FIG. 13, a semiconductor device having a reduced electrical resistance and an enhanced response is realizable by arranging the chip inductor 14 and the chip capacitor 15 outside of the semiconductor chip 3 and inside of the sealed body 7 (refer to FIG. 25).

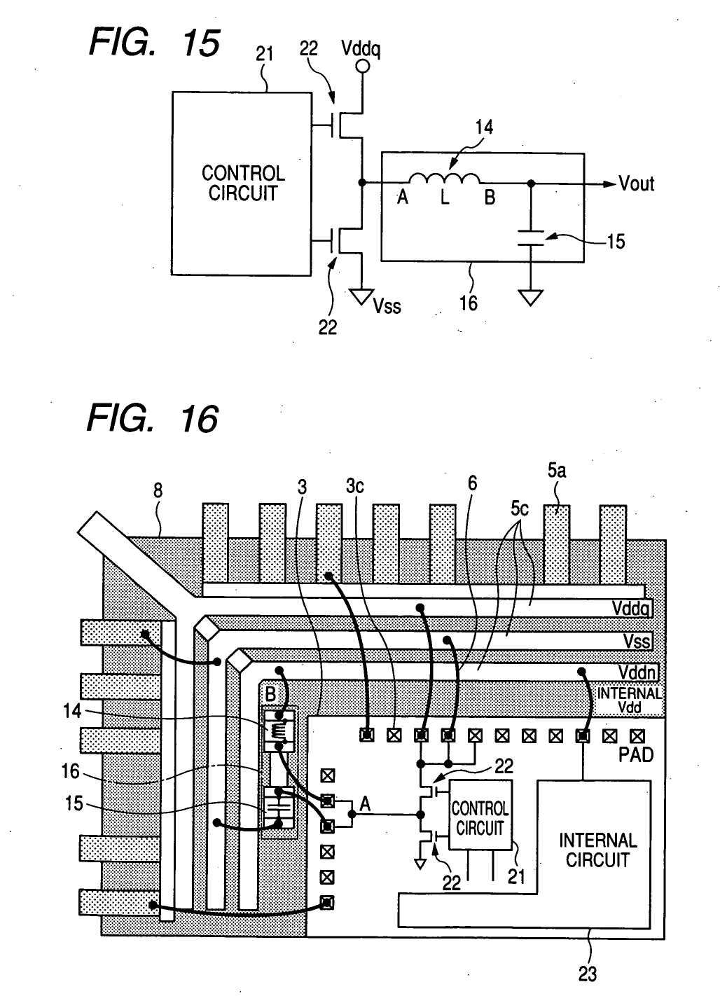

FIG. 15 is a circuit diagram of a DC-DC converter (voltage down circuit) in which a LC filter 16, which consists of a chip inductor 14 and a chip capacitor 15, have been arranged between a chip and inner leads. Although the current generated by the switching of the transistors 22 of each high side/low side connected to the control circuit 21 becomes pulse-like and is applied as a pulsating flow-like current to the UC of an inductance/capacity load, the current in that case serves as I=Io(DC)−(ΔVo/L)×Δt (pulsating flow), and if L is large, the current of pulsating flow will become small. And, t being short (frequency being high), the current of pulsating flow becomes small similarly. Then, the part which cannot secure a big inductance Lby internal inclusion is covered by making a parasitic element small by incorporating L and C in a package and making the frequency high at the grade which can drive a big load. By allotting the space occupied by the bar lead 5c for power supplies to the chip capacity C, the capacitor (C), which is linked to an output, can make the capacitance C greatly securable, and this can make the pulsating flow still lower and more smooth.

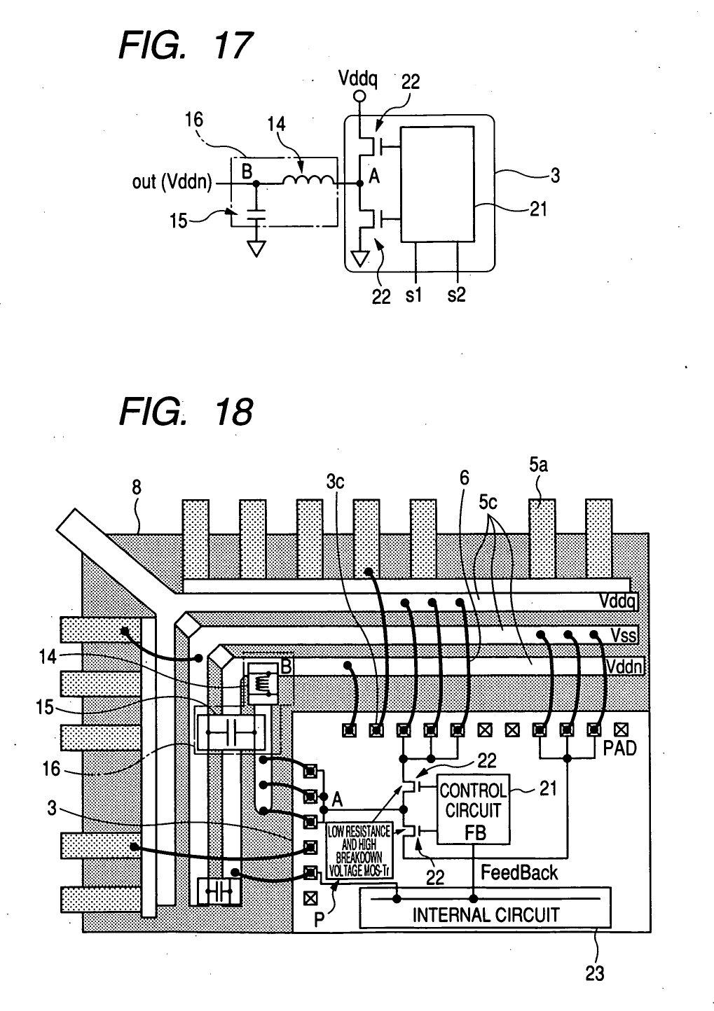

An example of the voltage down circuit which includes the circuit composition shown in FIG. 15 in the semiconductor device of this Embodiment 1 is shown in FIGS. 16 and 17.

The semiconductor device shown in FIG. 16, has a voltage down circuit containing the chip inductor 14, which is the first passive part which has been arranged outside of the semiconductor chip 3 and inside of the sealed body 7 (refer to FIG. 25), and which was provided with the inductance element, and the chip capacitor 15 which is the second passive part, which is arranged in the same domain as the chip inductor 14, and which has a capacitance element. Furthermore, the chip inductor 14 and the chip capacitor 15 are arranged on the sheet member 8 in the area which is located between the bar lead 5c, that is arranged as the innermost among the three bar leads 5c, and the semiconductor chip 3. Vddn at the innermost among the three bar leads 5c is connected with the internal circuit 23 of the semiconductor chip 3 via a wire 6.

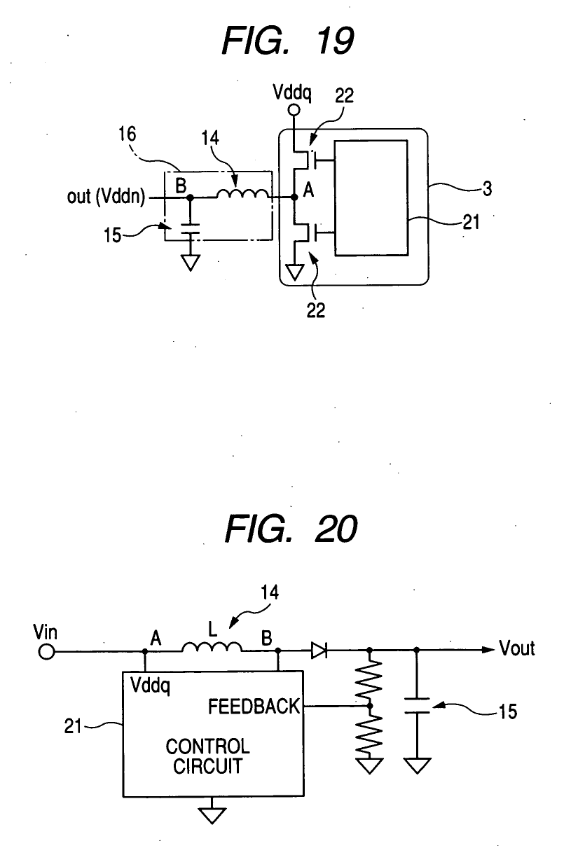

On the other hand, the chip inductor 14 and the chip capacitor 15 are mounted on the bar lead 5c used for the supply of power, and the capacity of the power supply is strengthened with the voltage down circuit of the semiconductor device shown in FIGS. 18 and 19. Therefore, connection with the bar lead 5c of the chip inductor 14 or the chip capacitor 15 is in the form of a direct solder connection, without using the wire 6. A MOSFET(Metal Oxide Semiconductor Field Effect Transistor) of low resistance and high breakdown voltage is used for the transistor 22 shown in the P section of FIG. 18.

Since the control circuit 21 is included inside of a chip, as shown in FIG. 19, it is also possible to raise the frequency, and the feedback (Feed Back) can also be performed frequently. That is, the ON/OFF control with the transistor 22 is accelerable.

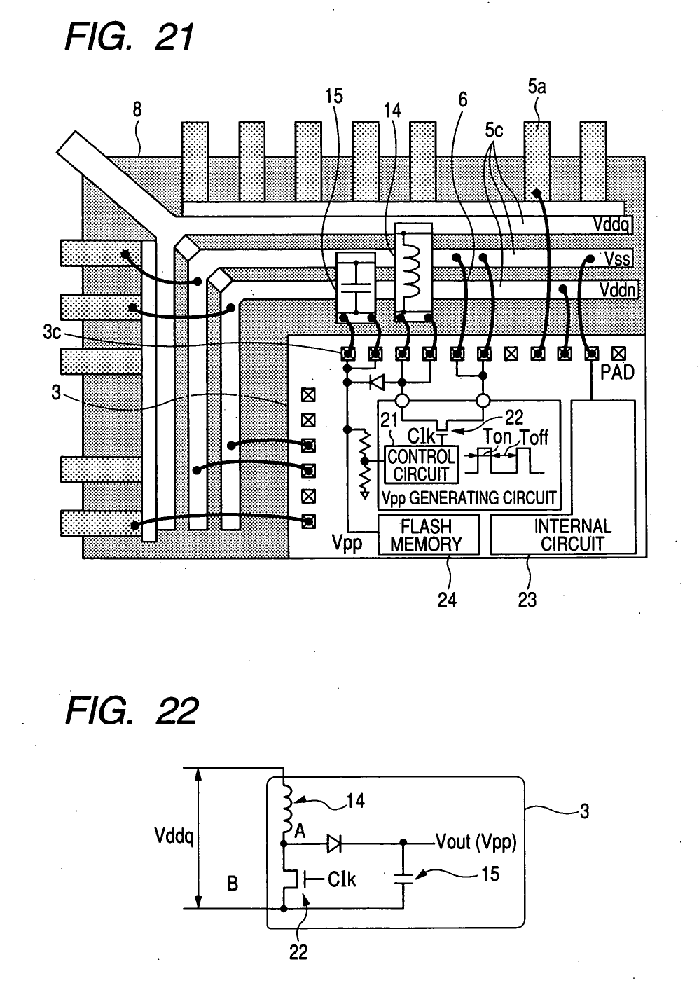

FIG. 20 is a general circuit diagram of a boost circuit containing a chip inductor (first passive part) 14 and a chip capacitor (second passive part) 15. An example of the boost circuit which includes the composition of this boost circuit in the semiconductor device of this Embodiment 1 is shown in FIGS. 21 and 22.

Also, in the composition shown in FIG. 21, both the chip inductor 14 and the chip capacitor 15 are arranged outside of the semiconductor chip 3 and inside of the sealed body 7 (refer to FIG. 25), and both are mounted on the bar leads 5c. Vpp shown in FIGS. 21 and 22 is a high voltage for use in the writing of the flash memory 24, and the Vpp level can be adjusted by feeding back a clock-on Ton time level. This boost circuit can operate as an input power supply, in which Vout serves as Vout=((Ton+Toff)/Toff)×Vddq, which Vout is several times Vddq.

According to the semiconductor device of this Embodiment 1, as mentioned above, in the QFP 1 which has chip parts, by arranging the chip parts in the area between the semiconductor chip 3 and the plurality of inner leads 5a, and beneath the wire 6, as shown in FIG. 28, the empty space beneath the wire 6, and between the semiconductor chip 3 and the inner leads 5a can be effectively used. Thereby, the miniaturization of the QFP 1 which has chip parts can be attained.

By arranging chip parts inside the sealed body 7 of the QFP 1, the loss by a parasitic element (R/C/L) can be reduced, as compared with the case where chip parts are mounted outside of the QFP 1, and the circuit can be made highly efficient. As a result, improvement in the electrical property of the QFP 1 which has chip parts can be attained.

By arranging chip parts outside of the semiconductor chip 3 and inside of the sealed body 7, in addition to being able to control enlargement of the semiconductor chip 3, a reduction of the number of parts mounted on a mounting board can be attained. Thereby, simplification of the mounting process of the QFP 1 can be attained.

A change of an inductance element accompanying a change of product specification can be easily effected by arranging the chip inductor 14, which is the first passive part that has an inductance element, outside of the semiconductor chip 3 and inside of the sealed body 7.

Furthermore, enlargement of the semiconductor chip 3 can be prevented by arranging the chip inductor 14, which constitutes an inductance element disposed outside of the semiconductor chip 3 and inside of the sealed body 7 (referring to FIG. 25). As a result, a decrease of the number of picking of the semiconductor chip 3 and a drop in the yield of the semiconductor chip 3 can be controlled. Thereby, it is possible to prevent a cost overrun of the semiconductor chip 3.

In the QFP 1, the semiconductor chip 3 is formed of silicon, for example, and the wire 6 is a gold wire, for example. The sealed body 7 is formed of a thermosetting epoxy resin, for example. The inner lead 5a, the outer lead 5b, and the bar lead 5c are formed of a thin plate material in the form of a copper alloy, for example. The sheet member 8 is formed of insulating thin board material, such as a glass epoxy resin and ceramics, for example. However, the sheet member 8 also may be formed using a member in which an insulating adhesive layer is formed on a thin metal plate (heat spreader), for example.

Next, a method of manufacture of the QFP 1 of this Embodiment 1 will be explained.

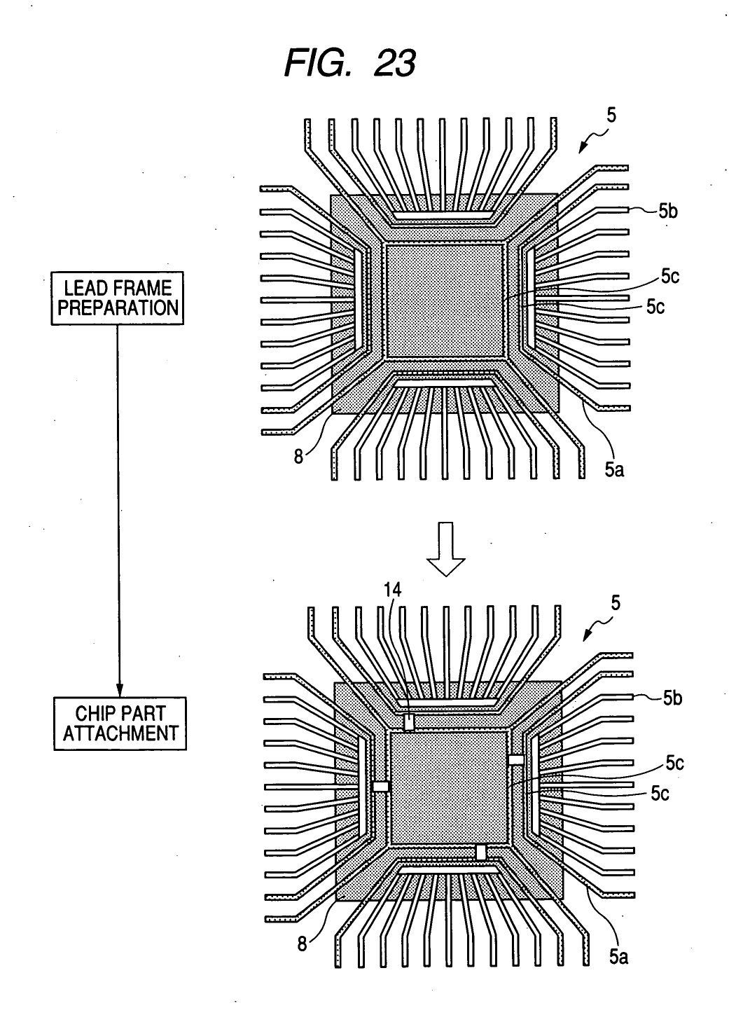

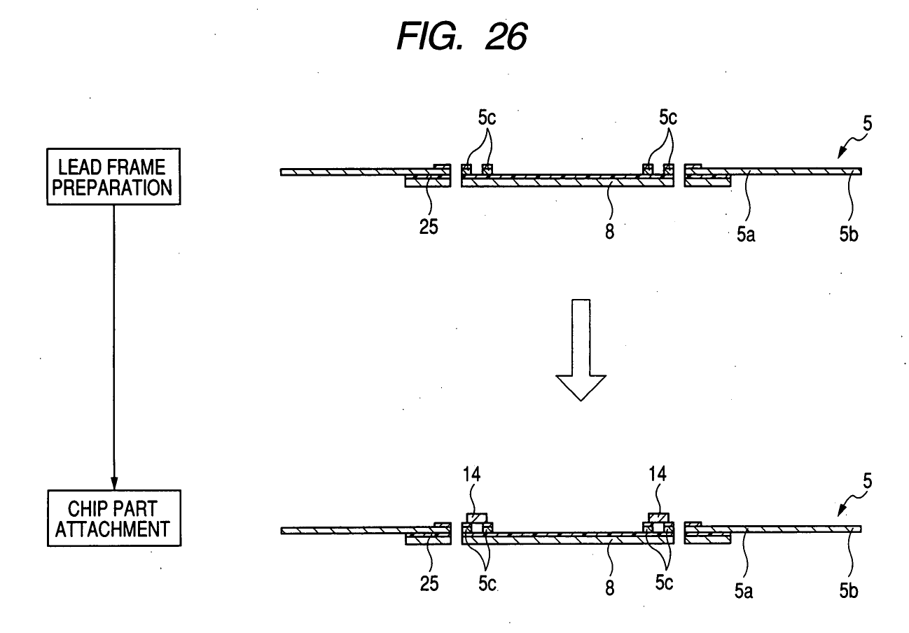

First, the lead frame 5, which has inner leads 5a and outer leads 5b, constituting a plurality of leads, and a thin sheet member 8, is prepared, as shown in FIGS. 23 and 26. That is, in the lead frame 5, the end parts of a plurality of inner leads 5a, which surround the sheet member 5, are joined via insulating adhesives 25 to the sheet member 8. The sheet member 8 may be an insulating number formed of polyimide tape, etc., and it also may be a metal heat spreader, etc.

Along with the lead sequence of a plurality of inner leads 5a, a plurality of bar leads 5c, which are common leads, are arranged in the lead frame 5 of this Embodiment 1 in the area outside of a chip mounting part and inside of the end parts of the plurality of inner leads 5a on the sheet member 8.

Then, chip part attachment, as shown in FIGS. 23 and 26, is performed. That is, the chip parts, which are surface mounting parts, are mounted area outside of a chip mounting part and inside of the end parts of a plurality of inner leads 5a on the sheet member 8. Here, a chip inductor 14 is mounted on the bar leads 5c as an example of the chip parts.

In this case, if the chip parts are to be insulated from the bar leads 5c, when mounting the chip parts, such as the chip inductor 14, on the bar leads 5c, the chip inductor 14 is mounted on the bar leads 5c using an insulating adhesive, etc. To connect the chip parts with the bar leads 5c electrically, when mounting the chip parts, such as the chip inductor 14, on the bar leads 5c, the chip inductor 14 is connected on the bar leads 5c using conductive paste material, such as silver paste and solder paste.

When chip parts are mounted via silver paste, processing to bake the silver paste is performed before mounting the semiconductor chip 3, after chip part mounting is complete. On the other hand, when chip parts are mounted via solder paste, reflow processing of the solder paste is performed before mounting the semiconductor chip 3, after chip part mounting is complete.

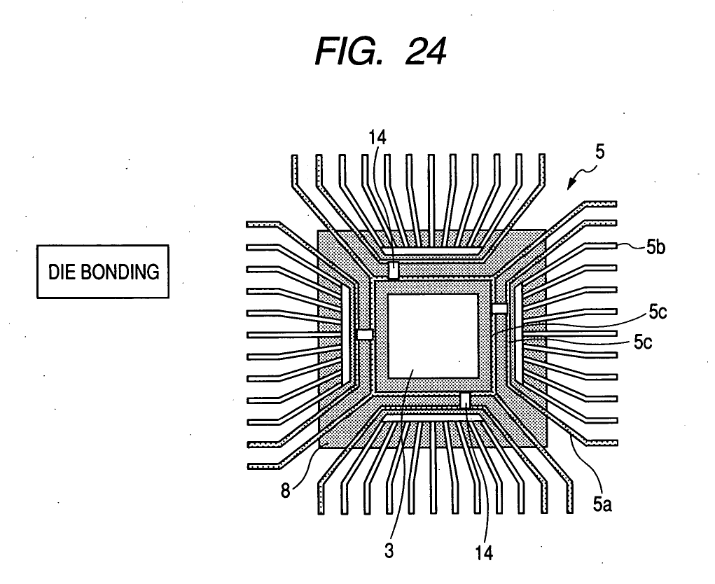

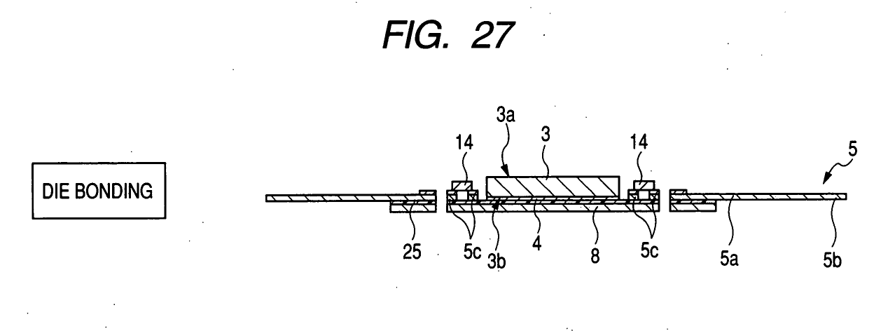

Then, as shown in FIGS. 24 and 27, die bonding in which the semiconductor chip 3 is mounted on the chip mounting part of the sheet member 8, is performed.

Thus, in this Embodiment 1, since the bake processing and reflow processing after adhesion of the chip parts are performed before mounting the semiconductor chip 3, by mounting the semiconductor chip 3 after completion of mounting of the chip parts, it is possible to prevent pollution of the semiconductor chip 3.

Furthermore, stabilization of the lead frame can be attained by mounting chip parts on the lead frame 5 ahead of the semiconductor chip 3, and, since the potential for generation of defective goods, such as due to a wire short-circuit and wire cutting, is reduced, damage to the wire 6 can be prevented.

Then, wire bonding is performed as shown in FIGS. 25 and 28. That is, a plurality of pads 3c on the main surface 3a of the semiconductor chip 3 and a plurality of inner leads 5a are each electrically connected using a plurality of conductive wires 6, respectively. In that case, as shown in FIG. 28, at least one of the plurality of wires 6 jumps over a chip part top and connects with the inner lead 5a.

Then, a resin molding is performed, as shown in FIGS. 25 and 28. That is, resin molding of the semiconductor chip 3, a plurality of inner leads 5a, and a plurality of wires 6 is carried out, and the sealed body 7 is formed.

Then, while cutting and separating a plurality of outer leads 5b and individually separating them from the lead frame 5, each outer lead 5b is bent in the shape of a gull wing, and the assembly of the QFP 1 is completed.

### Embodiment 2

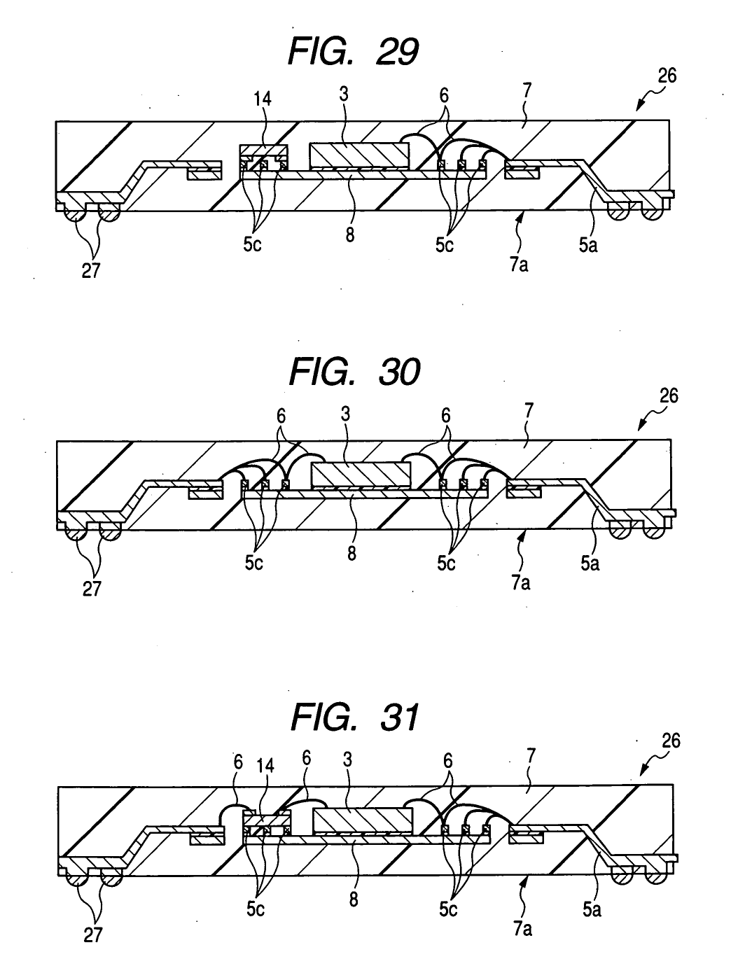

FIG. 29 is a sectional view showing an example of the structure of the semiconductor device of Embodiment 2 of this invention; FIG. 30 is a sectional view showing an example of a structure in which chip parts are not mounted in the semiconductor device as shown in FIG. 29; and FIG. 31 is a sectional view showing the structure of a semiconductor device representing the modification of Embodiment 2 of this invention.

The semiconductor device of this Embodiment 2, as shown in FIGS. 29 and 30, is a QFN(Quad Flat Non-leaded-Package) 26 on which a plurality of solder plating parts 27, which serve as external terminals, have been arranged with the circumferential edge of the back 7a of the sealed body 7. That is, a part of each inner lead 5a is exposed to the circumferential edge of the back 7a of the sealed body 7, and the solder plating part 27 is formed in this exposed part.

Also, in the QFN 26 of this Embodiment 2, like the QFP 1 of Embodiment 1, a chip part, such as the chip inductor 14, is mounted in the empty domain between the semiconductor chip 3 and the end parts of the inner leads 5a, and the same effect as the QFP 1 of Embodiment 1 can be attained.

As for the QFN 26 shown in FIG. 29, a chip part, such as the chip inductor 14, is electrically connected on the bar leads 5c directly by solder, etc. As for the QFN 26 shown in FIG. 31, a chip part is fixed on the bar leads 5c via an insulating adhesive, etc., so as to be insulated from the bar leads 5c. Therefore, in the case of the QFN 26 shown in FIG. 31, the chip parts are electrically connected with the inner lead 5a or the semiconductor chip 3 via a wire 6.

As to the other structures in the QFN 26 of this Embodiment 2, since they are the same as those of the QFP 1 of Embodiment 1, a repeated explanation thereof is omitted.

As mentioned above, although the present invention has been specifically explained based on various embodiments of this invention, it cannot be overemphasized that this invention is not limited to the embodiments of the described herein invention, and the invention can be changed variously in a range which does not deviate from the gist of the invention.

For example, as to the attachment of the chip parts in a semiconductor device according to Embodiments 1 and 2, the attachment may be a direct electrical connection using solder or silver paste, or it may be a connection using an insulating adhesion material.

As for the semiconductor device of Embodiments 1 and 2, at least one chip part may be mounted in the area between the semiconductor chip 3 and the inner leads 5a, and the chip part may be a surface mounting part, such as a capacitor, a resistor, or an inductor, etc.

Although the semiconductor device of Embodiments 1 and 2 was described for a case in which the bar lead 5c, which is a common lead, was arranged between the semiconductor chip 3 and the end parts of the inner leads 5a, the common lead of the bar lead 5c, etc., does not necessarily need to be arranged in the said semiconductor device.

The Embodiments 1 and 2 of the semiconductor device has been described for the case where a chip part, such as the chip inductor 14, is arranged between the semiconductor chip 3 and the inner leads 5a on the bar lead 5c. However, on the sheet member 8, the chip part, such as the chip inductor 14, may be arranged between the bar lead 5c and the inner leads 5a, while bringing the bar lead 5c close to the chip side and establishing space in the circumference of the sheet member 8.

This invention is suitable for application to an electronic device and a semiconductor device, and their manufacturing methods.

1. A semiconductor device comprising:
a plurality of leads;
a sheet member connected to each end part of the plurality of leads;
a semiconductor chip having a semiconductor element and a plurality of electrodes in a main surface thereof, being arranged inside the plurality of leads, and being further connected with the sheet member;
a plurality of conductive wires which connect electrically the electrodes of the semiconductor chip, and the plurality of leads, respectively; and
a chip part being a surface mounting part, which is arranged at a lower part of the wire in an area between the semiconductor chip and the plurality of leads.

2. A semiconductor device according to claim 1, wherein
1 or a plurality of common leads are arranged along with the lead sequence of the plurality of leads in the area between the semiconductor chip and the plurality of leads, and the chip part is mounted on the common lead.

3. A semiconductor device according to claim 2, wherein
the chip part is electrically connected with the common lead by solder connection.

4. A semiconductor device according to claim 2, wherein
the chip part is connected with the common lead via insulating adhesive.

5. A semiconductor device according to claim 1, wherein
a plurality of common leads are arranged along with the lead sequence of the plurality of leads in the area between the semiconductor chip and the plurality of leads; and
the chip part is arranged in an area between the common lead arranged in the innermost part of the plurality of common leads, and the semiconductor chip.

6. A semiconductor device according to claim 1, wherein
the chip part includes an element selected from the group consisting of a resistance element, an inductance element, and a capacitance element.

7. A semiconductor device according to claim 1, wherein
the chip part has an ESD protection element.

8. A semiconductor device according to claim 1, wherein
the chip part has an EMC protection element.

9. A semiconductor device according to claim 1, wherein
the chip part has a bypass capacitance element.

10. A semiconductor device according to claim 1, wherein
the chip part has a dumping resistance element.

11. A semiconductor device comprising:
a plurality of leads;
a sheet member connected to each end part of the plurality of leads;
a semiconductor chip having a semiconductor element and a plurality of electrodes in a main surface thereof, being arranged inside the plurality of leads, and being further connected with the sheet member;
a plurality of conductive wires which connect electrically the electrodes of the semiconductor chip, and the plurality of leads, respectively;
a sealed body sealing the semiconductor chip and the plurality of wires; and
a first passive part provided with an inductance element, that is arranged in the outside of the semiconductor chip and in the inside of the sealed body.

12. A semiconductor device according to claim 11, wherein
a second passive part having a capacitance element is arranged in the outside of the semiconductor chip and in the inside of the sealed body; and
a voltage down circuit containing the first passive part and the second passive part is included.

13. A semiconductor device according to claim 11, wherein
a second passive part having a capacitance element is arranged in the outside of the semiconductor chip and in the inside of the sealed body; and
a boost circuit containing the first passive part and the second passive part is included.

14. A semiconductor device according to claim 11, wherein
a second passive part having a capacitance element is arranged in the outside of the semiconductor chip and in the inside of the sealed body;
1 or a plurality of common leads are arranged along with the lead sequence of the plurality of leads in an area between the semiconductor chip and the plurality of leads; and
the first passive part and the second passive part are mounted on the common lead.

15. A semiconductor device according to claim 11, wherein
a second passive part having a capacitance element is arranged in the outside of the semiconductor chip and in the inside of the sealed body;
a plurality of common leads are arranged along with the lead sequence of the plurality of leads in an area between the semiconductor chip and the plurality of leads; and
the first passive part and the second passive part are arranged in an area between the common lead arranged in the innermost part of the plurality of common leads, and the semiconductor chip.

16. A manufacturing method of a semiconductor device assembled using a lead frame having a plurality of leads and a sheet member connected to end parts of the plurality of leads, comprising the steps of:
(a) preparing the lead frame to which the sheet member and the end parts of the plurality of leads were connected via insulating adhesive;
(b) mounting a chip part being a surface mounting part in an area in the outside of a chip mounting part and in the inside of the plurality of leads in the sheet member;
(c) after the step (b), mounting a semiconductor chip in the chip mounting part of the sheet member;
(d) connecting each of the plurality of leads with a plurality of electrodes of a main surface of the semiconductor chip electrically with a plurality of conductive wires, respectively;
(e) performing resin molding of the semiconductor chip and the plurality of leads, and forming a sealed body; and
(f) individually separating the plurality of leads from the lead frame.

17. A manufacturing method of a semiconductor device according to claim 16, wherein
after preparing the lead frame about which 1 or a plurality of common leads have been arranged along with the lead sequence of the plurality of leads in the area in the outside of the chip mounting part and in the inside of the plurality of leads of the sheet member in the step (a), the chip part is mounted on the common lead in the step (b).

18. A manufacturing method of a semiconductor device according to claim 16, wherein
in the step (b), the chip part is mounted via silver paste, and bake processing is performed after the mounting.

19. A manufacturing method of a semiconductor device according to claim 16, wherein
in the step (b), the chip part is mounted via solder paste, and reflow processing is performed after the mounting.
